(19) United States
(12) Patent Application Publication
(10) Pub. No.: US 2023/0062182 A1
(43) Pub. Date: Mar. 2, 2023

(54) SYSTEMS AND METHODS FOR CHANGING AIRFLOW DIRECTION OF AN AIR MOVER MODULE

(71) Applicant: Dell Products L.P., Round Rock, TX (US)

(72) Inventors: Kannan KARUPPIAH, Fremont, CA (US); Shree RATHINASAMY, Round Rock, TX (US)

(73) Assignee: Dell Products L.P., Round Rock, TX (US)

(21) Appl. No.: 17/465,551

(22) Filed: Sep. 2, 2021

(51) Int. Cl. F24F 11/63; G05B 19/042; F04D 25/06; H05K 7/20; F24F 11/74

(52) U.S. Cl. CPC F24F 11/63; G05B 19/042; F04D 25/06; H05K 7/20136; F24F 11/74; G05B 2219/2614

(57) ABSTRACT

A method for changing an airflow direction of an air mover of an information handling system may include mechanically translating the air mover in a linear direction from a closed position relative to a chassis configured to enclose components of the information handling system in which the air mover is enclosed by the chassis to an open position in which the air mover is drawn from the chassis, via a pair of rails mechanically coupled between the air mover and the chassis. The method may also include mechanically rotating the air mover 180 degrees relative to the pair of rails about an axis generally perpendicular to the linear direction, via a base mechanically interfaced between the air mover and the pair of rails. The method may further include mechanically translating the air mover from the open position to the closed position via the rails.

### TECHNICAL FIELD

The present disclosure relates in general to information handling systems, and more particularly to cooling of information handling system components using airflow driven by one or more air movers, and in particular, systems and methods for changing airflow direction of an air mover module.

BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

As processors, graphics cards, random access memory (RAM) and other components in information handling systems have increased in clock speed and power consumption, the amount of heat produced by such components as a side-effect of normal operation has also increased. Often, the temperatures of these components need to be kept within a reasonable range to prevent overheating, instability, malfunction and damage leading to a shortened component lifespan. Accordingly, air movers (e.g., cooling fans and blowers) have often been used in information handling systems to cool information handling systems and their components.

Networking switches often include air movers and power supply unit (PSU) modules. Typically, it may be desirable that air mover modules and PSU modules be in the same direction of airflow. Many information handling systems, including network switches, are designed such that airflow can be in a forward direction (e.g., from a front of an information handling system to a rear of the information handling system) or a reverse direction (e.g., from a rear of the information handling system to the front of the information handling system). A datacenter physical layout of characteristics of a cooling system may determine the optimal airflow direction. Traditionally, different air mover modules are used depending on whether airflow is desired in the forward direction or the reverse direction.

Incorrect airflow direction may lead to high temperatures within an information handling system, which may negatively affect operability of components. In the case that a user orders air mover modules with incorrect airflow direction, the user may need to replace such air mover modules with air mover modules having the correct airflow direction, which may be time consuming. In some instances, incorrect airflow direction may go unnoticed, and users may notice an issue only after significant increases in temperature that lead to high air mover speed that result in loud noise from air movers.

### SUMMARY

In accordance with the teachings of the present disclosure, the disadvantages and problems associated with thermal control of information handling resources may be substantially reduced or eliminated.

In accordance with embodiments of the present disclosure, an information handling system may include a chassis configured to house components of the information handling system, an air mover configured to drive airflow to cool one or more components of the information handling system, and a mechanical assembly configured to mechanically couple the air mover to the chassis. The mechanical assembly may include a pair of rails mechanically coupled to the chassis and a base mechanically interfaced between the air mover and the rails. The air mover may be slidably coupled to the chassis via the mechanical assembly such that the air mover is mechanically translatable in a linear direction relative to the chassis between a closed position in which the air mover is enclosed by the chassis and an open position in which the air mover is drawn from the chassis. The air mover may be rotatably coupled to the base such that the air mover is rotatable relative to the pair of rails about an axis substantially perpendicular to the linear direction when the air mover is drawn into the open position.

In accordance with these and other embodiments of the present disclosure, a method for changing an airflow direction of an air mover of an information handling system may include mechanically translating the air mover in a linear direction from a closed position relative to a chassis configured to enclose components of the information handling system in which the air mover is enclosed by the chassis to an open position in which the air mover is drawn from the chassis, via a pair of rails mechanically coupled between the air mover and the chassis. The method may also include mechanically rotating the air mover 180 degrees relative to the pair of rails about an axis generally perpendicular to the linear direction, via a base mechanically interfaced between the air mover and the pair of rails. The method may further include mechanically translating the air mover from the open position to the closed position via the rails.

In accordance with these and other embodiments of the present disclosure, a method may include mechanically coupling an air mover configured to drive airflow to cool one or more components of an information handling system to a chassis configured to house components of the information handling system. Mechanically coupling the air mover to the chassis may include mechanically coupling a pair of rails to the chassis and mechanically interfacing a base between the air mover and the rails, such that the air mover is slidably coupled to the chassis via the mechanical assembly such that the air mover is mechanically translatable in a linear direction relative to the chassis between a closed position in which the air mover is enclosed by the chassis and an open position in which the air mover is drawn from the chassis, and the air mover is rotatably coupled to the base such that the air mover is rotatable relative to the pair of rails about an axis substantially perpendicular to the linear direction when the air mover is drawn into the open position.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of an example information handling system, in accordance with embodiments of the present disclosure; and

FIGS. 2A-2E illustrate a top plan view of selected components of the information handling system shown in FIG. 1, and further illustrate a method for changing airflow direction of an air mover, in accordance with embodiments of the present disclosure.

### DETAILED DESCRIPTION

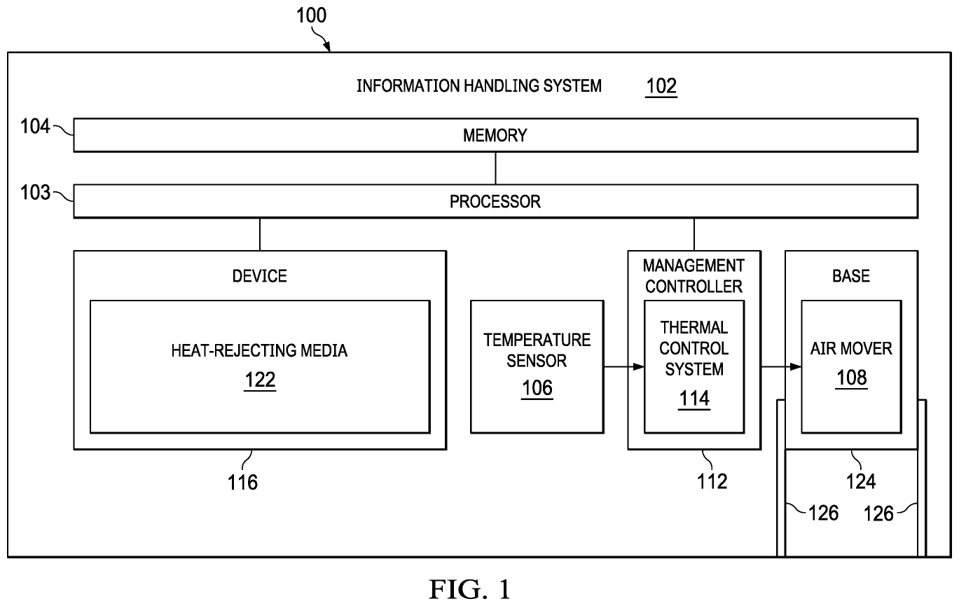

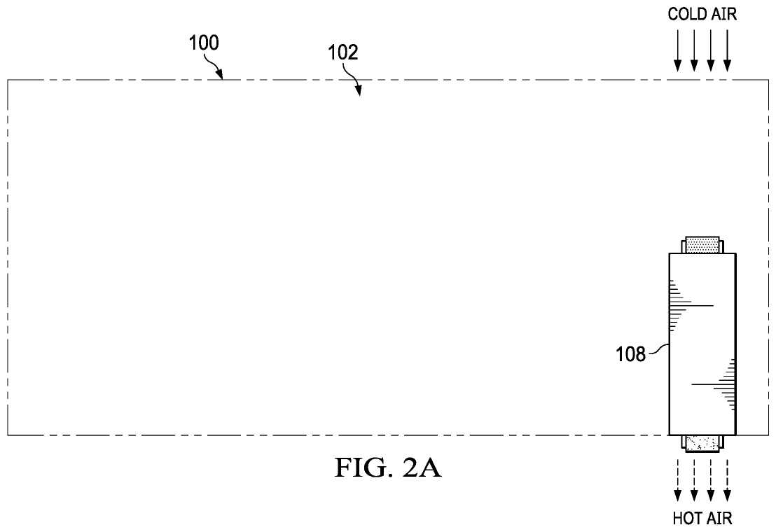

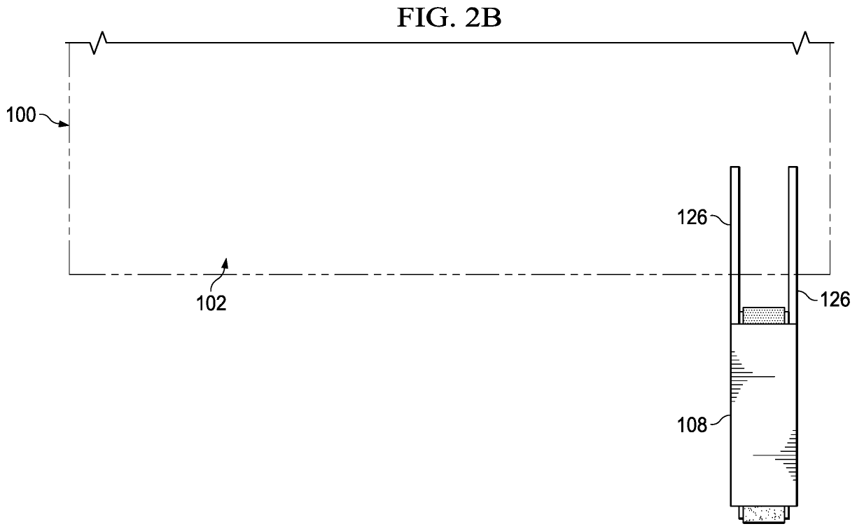

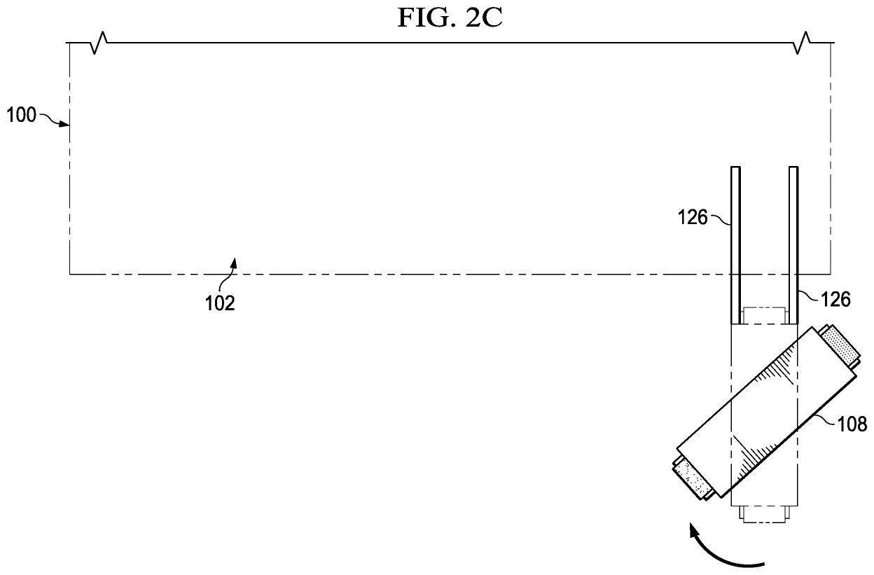

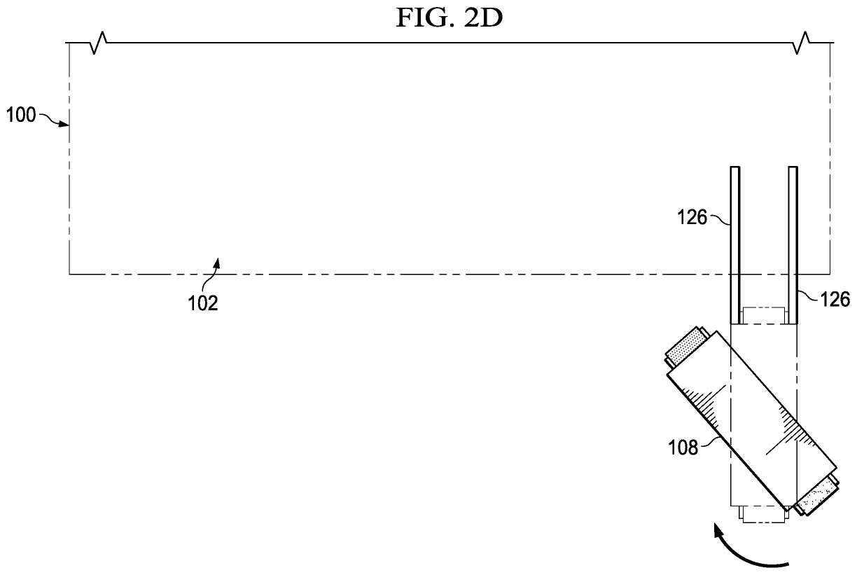

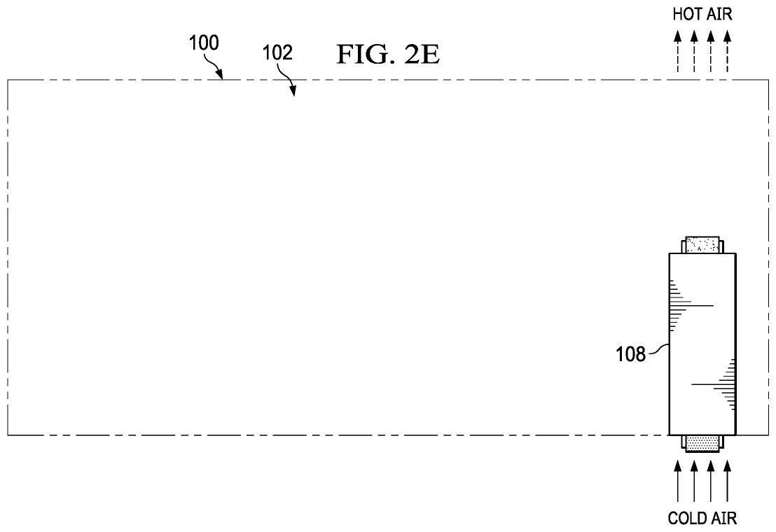

Preferred embodiments and their advantages are best understood by reference to FIGS. 1 through 2E, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a PDA, a consumer electronic device, a network storage device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, buses, memories, I/O devices and/or interfaces, storage resources, network interfaces, motherboards, integrated circuit packages; electro-mechanical devices (e.g., air movers), displays, and power supplies.

FIG. 1 illustrates a block diagram of an example information handling system 102, in accordance with embodiments of the present disclosure. In some embodiments, information handling system 102 may comprise a server chassis configured to house a plurality of servers or “blades.” In other embodiments, information handling system 102 may comprise a personal computer (e.g., a desktop computer, laptop computer, mobile computer, and/or notebook computer). In yet other embodiments, information handling system 102 may comprise a storage enclosure configured to house a plurality of physical disk drives and/or other computer-readable media for storing data. In yet other embodiments, information handling system 102 may include a network switch. As shown in FIG. 1, information handling system 102 may include a chassis 100 housing a processor 103, a memory 104, a temperature sensor 106, an air mover 108, a management controller 112, a device 116, heat-rejecting media 122, and a mechanical assembly comprising a base 124 and a pair of rails 126 for mechanically coupling air mover 108 to chassis 100.

Processor 103 may comprise any system, device, or apparatus operable to interpret and/or execute program instructions and/or process data, and may include, without limitation a microprocessor, microcontroller, digital signal processor (DSP), application specific integrated circuit (ASIC), or any other digital or analog circuitry configured to interpret and/or execute program instructions and/or process data. In some embodiments, processor 103 may interpret and/or execute program instructions and/or process data stored in memory 104 and/or another component of information handling system 102.

Memory 104 may be communicatively coupled to processor 103 and may comprise any system, device, or apparatus operable to retain program instructions or data for a period of time. Memory 104 may comprise random access memory (RAM), electrically erasable programmable read-only memory (EEPROM), a PCMCIA card, flash memory, magnetic storage, opto-magnetic storage, or any suitable selection and/or array of volatile or non-volatile memory that retains data after power to information handling system 102 is turned off.

Air mover 108 may include any mechanical, electrical, or electro-mechanical system, apparatus, or device operable to move air and/or other gases in order to cool information handling resources of information handling system 102. In some embodiments, air mover 108 may comprise a fan (e.g., a rotating arrangement of vanes or blades which act on the air). In other embodiments, air mover 108 may comprise a blower (e.g., a centrifugal fan that employs rotating impellers to accelerate air received at its intake and change the direction of the airflow). In these and other embodiments, rotating and other moving components of air mover 108 may be driven by a motor.

In yet other embodiments, air mover 108 may comprise a solid-state fan or other similar device that may be used to generate an airflow with no moving mechanical parts. A solid-state fan may use the principle of electro-aerodynamic pumping, based on corona discharge, to generate an ionized airflow. A solid-state fan may have advantages over traditional mechanical air movers in that a solid-state fan may generate less noise and may be less susceptible to failure of mechanical parts.

The speed of airflow driven by air mover 108 (e.g., rotational speed of a motor or voltage potential difference used to generate ionized airflow) may be controlled by an air mover control signal communicated from thermal control system 114 of management controller 112.

In operation, air mover 108 may cool information handling resources of information handling system 102 by drawing cool air into an enclosure housing the information handling resources from outside the chassis, expelling warm air from inside the enclosure to the outside of such enclosure, and/or moving air across one or more heat sinks (not explicitly shown) internal to the enclosure to cool one or more information handling resources.

Management controller 112 may comprise any system, device, or apparatus configured to facilitate management and/or control of information handling system 102 and/or one or more of its component information handling resources. Management controller 112 may be configured to issue commands and/or other signals to manage and/or control information handling system 102 and/or its information handling resources. Management controller 112 may comprise a microprocessor, microcontroller, DSP, ASIC, field programmable gate array (“FPGA”), EEPROM, or any combination thereof. Management controller 112 also may be configured to provide out-of-band management facilities for management of information handling system 102. Such management may be made by management controller 112 even if information handling system 102 is powered off or powered to a standby state. In certain embodiments, management controller 112 may include or may be an integral part of a baseboard management controller (BMC), a remote access controller (e.g., a Dell Remote Access Controller or Integrated Dell Remote Access Controller), or an enclosure controller. In other embodiments, management controller 112 may include or may be an integral part of a chassis management controller (CMC).

As shown in FIG. 1, management controller 112 may include a thermal control system 114. Thermal control system 114 may include any system, device, or apparatus configured to receive one or more signals indicative of one or more temperatures within information handling system 102 (e.g., one or more signals from one or more temperature sensors 106), and based on such signals, calculate an air mover driving signal to maintain an appropriate level of cooling, increase cooling, or decrease cooling, as appropriate, and communicate such air mover driving signal to air mover 108. In these and other embodiments, thermal control system 114 may be configured to receive information from other information handling resources and calculate the air mover driving signal based on such received information in addition to temperature information. For example, as described in greater detail below, thermal control system 114 may receive configuration data from device 116 and/or other information handling resources of information handling system 102, which may include thermal requirements information of one or more information handling resources. In addition to temperature information collected from sensors within information handling system 102, thermal control system 114 may also calculate the air mover driving signal based on such information received from information handling resources.

Temperature sensor 106 may be any system, device, or apparatus (e.g., a thermometer, thermistor, etc.) configured to communicate a signal to management controller 112 or another controller indicative of a temperature within information handling system 102. In many embodiments, information handling system 102 may comprise a plurality of temperature sensors 106, wherein each temperature sensor 106 detects a temperature of a particular component and/or location within information handling system 102.

Device 116 may comprise any component information handling system of information handling system 102, including without limitation processors, buses, memories, I/O devices and/or interfaces, storage resources, network interfaces, motherboards, integrated circuit packages, electro-mechanical devices, displays, and power supplies.

As shown in FIG. 1, device 116 may have mechanically and thermally coupled thereto heat-rejecting media 122. Heat-rejecting media 122 may include any system, device, or apparatus configured to transfer heat from an information handling resource (e.g., device 116, as shown in FIG. 1), thus reducing a temperature of the information handling resource. For example, heat-rejecting media 122 may include a solid member thermally coupled to the information handling resource (e.g., heat spreader) such that heat generated by the information handling resource is transferred from the information handling resource into air surrounding the information handling resource. For example, in the embodiments represented by FIG. 1, heat-rejecting media 122 may be thermally coupled to device 116 and arranged such that heat generated by device 116 is transferred to air driven by air mover 108, as described in greater detail below.

In addition to processor 103, memory 104, temperature sensor 106, air mover 108, management controller 112, device 116, and heat-rejecting media 122, information handling system 102 may include one or more other information handling resources. In addition, for the sake of clarity and exposition of the present disclosure, FIG. 1 depicts only one air mover 108 and one device 116. In embodiments of the present disclosure, information handling system 102 may include any number of air movers 108 and devices 116. However, in some embodiments, approaches similar or identical to those used to cool device 116 as described herein may be employed to provide cooling of processor 103, memory 104, management controller 112, and/or any other information handling resource of information handling system 102.

To enable a user to change an airflow direction of air mover 108, air mover 108 may be rotatably coupled to base 124, wherein such base 124 may further be mechanically coupled to chassis 100 via a pair of rails 126. Changing airflow direction of air mover 108 is described in greater detail below with reference to FIGS. 2A-2E.

FIGS. 2A-2E illustrate a top plan view of selected components of information handling system 102, and further illustrate a method for changing airflow direction of air mover 108, in accordance with embodiments of the present disclosure. For purposes of clarity and exposition, FIGS. 2A-2E depict only a single air mover 108. However, in some embodiments, information handling system 102 may include an array of air movers 108. Furthermore, for purposes of clarity and exposition, base 124 is not explicitly depicted in FIGS. 2A-2E due to the fact that, in such a top plan view, base 124 may not be visible.

As shown in FIG. 2A, air mover 108 may be oriented in a first position relative to chassis 100, in which air mover 108 drives airflow such that cooled air is drawn from a front of information handling system 102 and warmed air is expelled through a rear of information handling system 102. The labels “front” and “rear” are arbitrary and used for purposes of convenience of exposition, and are not used to limit the scope of this disclosure. The arrangement shown in FIG. 2A may be considered to have a “normal” configuration of air mover 108.

In order to change an airflow direction of air mover 108 relative to chassis 100, air mover 108 may first be drawn from chassis 100 as depicted in FIG. 2B. As shown in FIG. 2B, air mover 108 may be mechanically coupled to chassis 100 via rails 126 (and base 124, now shown), such that air mover 108 may slide in a substantially linear manner relative to chassis 100 between a closed position (e.g., shown in FIG. 2A) to an open position (e.g., shown in FIG. 2B) in a manner similar to that of sliding a drawer in and out of a cabinet.

After drawing air mover 108 from chassis 100 as depicted in FIG. 2B, air mover 108 may be rotated relative to rails 126 as shown in FIG. 2C and FIG. 2D. To facilitate such rotation, base 124 may be mechanically interfaced between rails 126 and air mover 108, and air mover 108 may be mechanically coupled to base 124 such that air mover 108 may rotate relative to base 124 about an axis substantially perpendicular to the linear direction in which air mover 108 may be drawn from chassis 100 via rails 126. Although FIGS. 2C and 2D depict a clockwise rotation with respect to the perspective shown, a counterclockwise rotation may also be enabled and used.

After air mover 108 is rotated 180 degrees relative to rails 126, air mover 108 may be slid linearly on rails 126 to reinsert air mover 108 into chassis 100 as shown in

FIG. 2E. As shown in FIG. 2E, air mover 108 may be oriented in a second position relative to chassis 100, in which air mover 108 drives airflow such that cooled air is drawn from the rear of information handling system 102 and warmed air is expelled through the front of information handling system 102. The arrangement shown in FIG. 2E may be considered to have a “reverse” configuration of air mover 108.

In some embodiments, air mover 108 may have electrical connectivity (e.g., dual connectivity) to a printed circuit board and/or other components of information handling system 102 such that air mover 108 may draw power and/or communicate with other components of information handling system 102 in both the normal configuration and the reverse configuration.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. An information handling system comprising:
a chassis configured to house components of the information handling system;
an air mover configured to drive airflow to cool one or more components of the information handling system; and
a mechanical assembly configured to mechanically couple the air mover to the chassis, the mechanical assembly comprising:
a pair of rails mechanically coupled to the chassis; and
a base mechanically interfaced between the air mover and the rails;
wherein:
the air mover is slidably coupled to the chassis via the mechanical assembly such that the air mover is mechanically translatable in a linear direction relative to the chassis between a closed position in which the air mover is enclosed by the chassis and an open position in which the air mover is drawn from the chassis; and
the air mover is rotatably coupled to the base such that the air mover is rotatable relative to the pair of rails about an axis substantially perpendicular to the linear direction when the air mover is drawn into the open position.

2. The information handling system of claim 1, wherein the air mover comprises a solid-state fan.

3. The information handling system of claim 1, wherein the information handling system comprises a network switch.

4. A method for changing an airflow direction of an air mover of an information handling system, the method comprising:
mechanically translating the air mover in a linear direction from a closed position relative to a chassis configured to enclose components of the information handling system in which the air mover is enclosed by the chassis to an open position in which the air mover is drawn from the chassis, via a pair of rails mechanically coupled between the air mover and the chassis;
mechanically rotating the air mover 180 degrees relative to the pair of rails about an axis generally perpendicular to the linear direction, via a base mechanically interfaced between the air mover and the pair of rails; and
mechanically translating the air mover from the open position to the closed position via the rails.

5. The method of claim 4, wherein the air mover comprises a solid-state fan.

6. The method of claim 4, wherein the information handling system comprises a network switch.

7. A method comprising:
mechanically coupling an air mover configured to drive airflow to cool one or more components of an information handling system to a chassis configured to house components of the information handling system, wherein mechanically coupling the air mover to the chassis comprises:
mechanically coupling a pair of rails to the chassis; and
mechanically interfacing a base between the air mover and the rails;
such that:
the air mover is slidably coupled to the chassis via the mechanical assembly such that the air mover is mechanically translatable in a linear direction relative to the chassis between a closed position in which the air mover is enclosed by the chassis and an open position in which the air mover is drawn from the chassis; and
the air mover is rotatably coupled to the base such that the air mover is rotatable relative to the pair of rails about an axis substantially perpendicular to the linear direction when the air mover is drawn into the open position.

8. The method of claim 7, wherein the air mover comprises a solid-state fan.

9. The method of claim 7, wherein the information handling system comprises a network switch.
